(19) United States
(12) Patent Application Publication
(10) Pub. No.: US 2011/0006387 A1
(43) Pub. Date: Jan. 13, 2011

(54) SOLID-STATE IMAGING DEVICE

(76) Inventors: Motonari KATSUNO, Kyoto (JP); Ryohei MIYAGAWA, Kyoto (JP)

Correspondence Address: MCDERMOTT WILL & EMERY LLP, 600 13TH STREET, NW, WASHINGTON, DC, 20005-3096, US

(21) Appl. No.: 12/822,743

(22) Filed: Jun. 24, 2010

(30) Foreign Application Priority Data
Jul. 13, 2009 (JP) 2009-164859

(51) Int. Cl. H01L 27/146

(52) U.S. Cl. 257/433; 257/E27.133

(57) ABSTRACT

A photodiode is formed for each pixel of a semiconductor substrate. An insulating film is formed on the semiconductor substrate, the insulating film having a depressed portion over the photodiode. A buried film having a higher refractive index than the insulating film is formed in the depressed portion. The cross sectional area of the depressed portion along a plane parallel to the light-receiving surface of the semiconductor substrate gradually increases at positions further away from the light-receiving surface of the semiconductor substrate.

### CROSS-REFERENCE TO RELATED APPLICATION

This application claims priority to Japanese Patent Application No. 2009-164859 filed on Jul. 13, 2009, the disclosure of which including the specification, the drawings, and the claims is hereby incorporated by reference in its entirety.

### BACKGROUND

The present disclosure relates to a solid-state imaging device including a light-receiving portion such as a photoelectric transducer.

Typically, in a metal oxide semiconductor (MOS) sensor, for example, a photodiode is provided for each of pixels arranged in a two-dimensional matrix pattern on the light-receiving surface. A signal charge generated and accumulated in each photodiode when light is received is transferred to a floating diffusion by driving a complementary metal oxide semiconductor (CMOS) circuit, and read after being converted to a signal voltage.

In a solid-state imaging device such as a CMOS sensor described above, for example, a photodiode is formed on the surface of a semiconductor substrate, and an insulating film made of silicon oxide, or the like, is formed so as to cover the upper surface thereof. In an area of the insulating film excluding the photodiode area, a wiring layer is formed so as not to prevent light from entering the photodiode.

However, the area of the light-receiving surface of such a solid-state imaging device as described above has been decreased due to device miniaturization, which has led to a decrease in the light incidence efficiency and the deterioration in the sensitivity characteristic.

As a countermeasure against this, structures have been developed for condensing light by using on-chip lens or an inner-layer lens. Solid-state imaging devices have been developed where an optical waveguide for guiding incident light from outside onto the photodiode is provided in a portion of an insulting film over the photodiode.

Patent Document 1 discloses a solid-state imaging device in which a depressed portion is formed in a portion of an insulating film over the photodiode and filling the depressed portion with silicon nitride which is a material having a higher refractive index than silicon oxide (hereinafter, referred to as a high-refractive-index material), thus forming an optical waveguide for guiding the incident light onto the photodiode.

Patent Document 2 discloses a solid-state imaging device in which a depressed portion formed in a portion of an insulating film over the photodiode is filled with a silicon nitride film and a polyimide film in this order, thus forming an optical waveguide.

Patent Document 3 discloses a solid-state imaging device in which a depressed portion having a regular tapered shape is formed in a portion of an insulating film over the photodiode, and the depressed portion is filled with silicon nitride, thus forming an optical waveguide.

FIG. 6 is a cross-sectional view of a solid-state imaging device disclosed in Patent Document 1. As shown in FIG. 6, in a solid-state imaging device 31 disclosed in Patent Document 1, a first inter-layer insulating film 3a with a gate electrode 16 formed therein is layered on a substrate 1 with a light-receiving portion 2 and a channel region 17 formed therein. Provided over the gate electrode 16 is a first wire 4a obtained by burying copper into the first inter-layer insulating film 3a by a damascene method with a barrier layer 7 interposed between the first wire 4a and the first inter-layer insulating film 3a. A first anti-diffusion film 5a for preventing the diffusion of copper is provided on the upper surface of the first inter-layer insulating film 3a including the upper surface of the first wire 4a. Further layered on the anti-diffusion film 5a are a layer made of a second inter-layer insulating film 3b, a second wire 4b, and a second anti-diffusion film 5b, and a layer made of a third inter-layer insulating film 3c, a third wire 4c, and a third anti-diffusion film 5c, both structured as described above excluding the gate electrode 16. Here, the inter-layer insulating films 3b and 3c and the anti-diffusion films 5a, 5b, and 5c are selectively removed above the light-receiving portion 2, and a passivation film 12 made of a silicon nitride film is attached to the entire surface including this depressed portion (hereinafter, referred to as a waveguide depressed portion). Thus, the interface at which incident light 13 is partially reflected when entering the first inter-layer insulating film 3a from the passivation film 12 is only one interface 36a between the passivation film 12 and the first inter-layer insulating film 3a, and therefore a sufficient amount of the incident light 13 is incident on the light-receiving portion 2. The incident light 13 is reflected also at an interface 36b between the passivation film 12 and the second and third inter-layer insulating films 3b and 3c, to be incident on the light-receiving portion 2.

### Citation List

### Patent Document

PATENT DOCUMENT 1: Japanese Patent No. 4117672

PATENT DOCUMENT 2: Japanese Published Patent Application No. 2004-207433

PATENT DOCUMENT 3: Japanese Patent No. 4120543

### SUMMARY

Now, when a solid-state imaging device is downsized, the cell size decreases, and the opening width of the waveguide depressed portion also decreases, thus increasing the aspect ratio of the waveguide depressed portion. In such a case, when the waveguide depressed portion is filled with a high-refractive-index insulating film as disclosed in Patent Document 1, a void is formed in the waveguide depressed portion after the filling process. This is a phenomenon which occurs because the growth rate in the high-refractive-index insulating film formation on the side surface of the waveguide depressed portion is smaller than the growth rate in the high-refractive-index insulating film formation in the entrance portion of the waveguide depressed portion. In the presence of such a void, light entering the waveguide is scattered by the void, and therefore the light condensing efficiency onto the photodiode is significantly lowered from that when no waveguide is formed.

Also in the solid-state imaging device disclosed in Patent Document 2 or Patent Document 3, a void is formed when filling the waveguide depressed portion with the high-refractive-index insulating film, therefore it is not possible to avoid the problem described above.

In view of the above, an object of the present disclosure is to provide a solid-state imaging device capable of realizing a higher light condensing efficiency than when no waveguide is formed by filling a waveguide depressed portion with a high-refractive-index material without forming a void.

In order to achieve the object above, a solid-state imaging device according to the present disclosure includes: a semiconductor substrate having, on a side of a light-receiving surface thereof, an image sensing region in which a plurality of pixels are formed; a photodiode formed for each of the pixels of the semiconductor substrate; a signal reading portion formed for each of the pixels of the semiconductor substrate for reading a signal charge produced by the photodiode; an insulating film formed on the semiconductor substrate; a depressed portion formed in a portion of the insulating film over the photodiode; a first buried film covering a side surface and a bottom surface of the depressed portion and having a higher refractive index than the insulating film; and a second buried film formed on the first buried film so as to fill up the depressed portion and having a higher refractive index than the insulating film, wherein a cross sectional area of the depressed portion along a plane parallel to the light-receiving surface of the semiconductor substrate gradually increases at positions further away from the light-receiving surface of the semiconductor substrate.

In the solid-state imaging device according to the present disclosure, an area of the photodiode along a plane parallel to the light-receiving surface of the semiconductor substrate may be larger than an area of the bottom surface of the depressed portion and smaller than an opening area of an uppermost portion of the depressed portion.

In the solid-state imaging device according to the present disclosure, the insulating film may include a plurality of insulating layers each having a wire buried therein and having an anti-diffusion layer on an upper surface side thereof, and the bottom surface of the depressed portion may be formed at a position that is closer to the light-receiving surface of the semiconductor substrate than the anti-diffusion layer closest to the light-receiving surface of the semiconductor substrate. In this case, the solid-state imaging device may further include an etch-stop layer formed at a position that is closer to the light-receiving surface of the semiconductor substrate than the anti-diffusion layer closest to the light-receiving surface of the semiconductor substrate, wherein a distance from the light-receiving surface of the semiconductor substrate to the bottom surface of the depressed portion may be substantially equal to a distance from the light-receiving surface of the semiconductor substrate to an upper surface of the etch-stop layer. That is, the etch-stop layer may be formed in advance at a predetermined depth in the insulating film, and the insulating film may be etched by using the etch-stop layer, thereby forming the depressed portion reaching the etch-stop layer.

In the solid-state imaging device according to the present disclosure, the insulating film may be formed also in a pad region outside the image sensing region of the semiconductor substrate, a pad electrode may be formed on a portion of the insulating film in the pad region, the first buried film may be a passivation film formed on the insulating film so as to cover a portion of the pad electrode, and a distance from the light-receiving surface of the semiconductor substrate to an upper surface of the second buried film may be substantially equal to a distance from the light-receiving surface of the semiconductor substrate to an upper surface of a portion of the passivation film over the pad electrode. In this case, the second buried film may not be formed on a portion of the passivation film over the pad electrode.

In the solid-state imaging device according to the present disclosure, the first buried film may be a silicon nitride film.

In the solid-state imaging device according to the present disclosure, the second buried film is a resin layer. In this case, the resin layer may contain a siloxane-based resin or a polyimide-based resin.

According to the present disclosure, the cross sectional area of the waveguide depressed portion gradually increases at positions further away from the light-receiving surface of the semiconductor substrate. Therefore, even if the waveguide depressed portion has a large aspect ratio, by covering the side surface and the bottom surface of the waveguide depressed portion with a relatively thin first buried film, e.g., a silicon nitride film, it is possible to prevent the first buried film from blocking the entrance of the waveguide depressed portion to form a void in the waveguide depressed portion. Therefore, the second buried film, e.g., a resin layer, can be formed on the first buried film so as to completely fill up the waveguide depressed portion. That is, it is possible to fill up the waveguide depressed portion with a high-refractive-index material without forming a void therein, and it is therefore possible to maintain a high light condensing efficiency as compared with a case where no waveguide is formed. Therefore, it is possible to maximize the condensation of light from the lens onto the photodiode, which is the basic function of a solid-state imaging device such as an image sensor, and it is therefore possible to realize a solid-state imaging device with a high sensitivity.

Thus, the present disclosure makes it possible to fill up a waveguide depressed portion with a high-refractive-index material without forming a void therein, and is useful as a solid-state imaging device.

### BRIEF DESCRIPTION OF THE DRAWINGS

FIG. 1 is a cross-sectional view schematically showing a configuration of a solid-state imaging device according to a first embodiment of the present disclosure.

FIGS. 2A-2C are diagrams illustrating different light condensations for different structures of the waveguide depressed portion in the solid-state imaging device according to the first embodiment of the present disclosure.

FIGS. 3A and 3B are diagrams illustrating different light condensations for different structures of the waveguide depressed portion in the solid-state imaging device according to the first embodiment of the present disclosure.

FIG. 4 is a cross-sectional view showing a solid-state imaging device according to the first embodiment of the present disclosure where the thickness of the buried layer has variations.

FIG. 5 is a cross-sectional view schematically showing a configuration of a solid-state imaging device according to a variation of the first embodiment of the present disclosure.

FIG. 6 is a cross-sectional view showing a conventional solid-state imaging device.

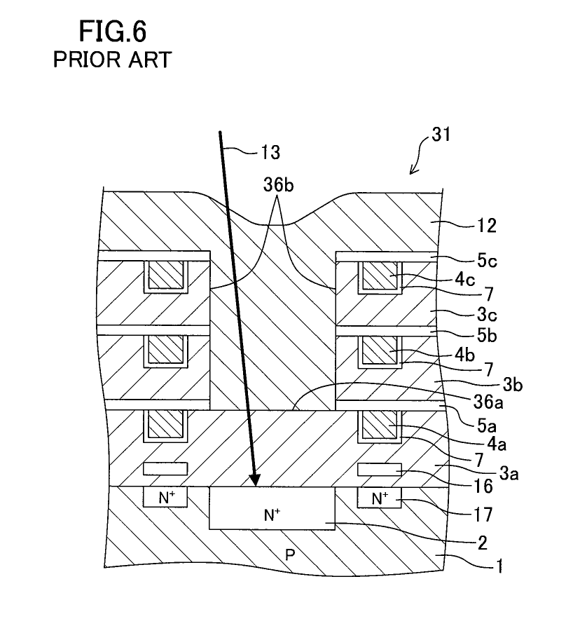

### DETAILED DESCRIPTION

A solid-state imaging device according to each embodiment of the present disclosure will now be described with reference to the drawings, with respect to a MOS image sensor (CMOS image sensor) as an example.

### First Embodiment

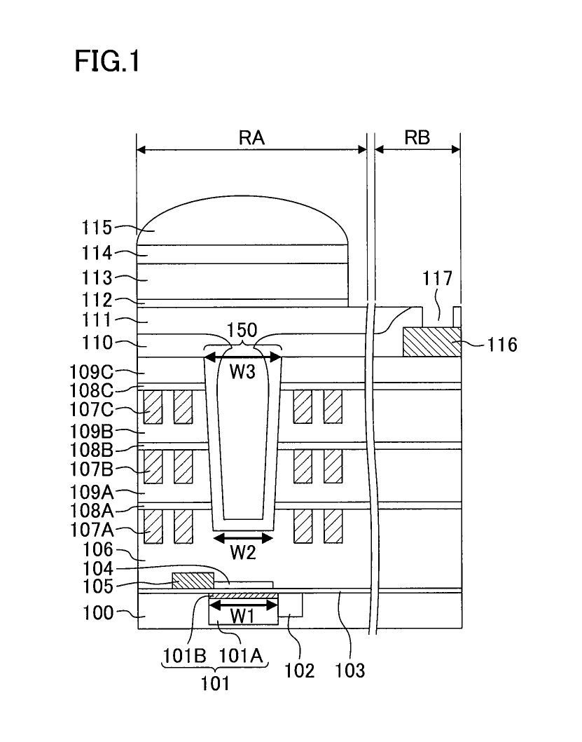

FIG. 1 is a cross-sectional view schematically showing a configuration of a solid-state imaging device according to a first embodiment, specifically a CMOS sensor. Note that FIG. 1 shows a configuration of one pixel from among a plurality of pixels provided in the image sensing region, together with a configuration of the pad electrode region.

As shown in FIG. 1, on the side of a light-receiving surface of a portion of a semiconductor substrate 100 in an image sensing region RA, a charge storing layer 101A of an n type, for example, is provided for each pixel, and a surface layer 101B of a p⁺-type, for example, is formed in a surface portion of the charge storing layer 101A. A photodiode (PD) 101 is formed by the pn junction between the charge storing layer 101A and the surface layer 101B. An isolation region 102 for electrically isolating the photodiode 101 is formed on the side of the light-receiving surface of the semiconductor substrate 100. A gate electrode 105 is formed on a portion of the semiconductor substrate 100 adjacent to the photodiode 101 with a gate insulating film 103 interposed between the gate electrode 105 and the semiconductor substrate 100. An anti-reflection insulating film 104 made of a silicon nitride film or a silicon oxide nitride film, for example, is formed on the photodiode 101 in order to prevent light incident on the photodiode 101 from being reflected by the substrate surface.

In the present embodiment, a floating diffusion is formed for each pixel in a surface portion of the photodiode 101 under the gate electrode 105 as a signal reading portion for reading a signal charge produced and stored in the photodiode 101 or a voltage corresponding to the signal charge. Thus, a signal charge can be transferred by applying a voltage to the gate electrode 105.

As shown in FIG. 1, a first insulating film 106 made of silicon oxide, for example, is formed on the semiconductor substrate 100 so as to cover the photodiode 101 and the gate electrode 105. A first copper wire 107A is formed in the first insulating film 106 by a damascene method, for example. A first anti-diffusion film 108A made of silicon carbide or silicon nitride, for example, is formed on the upper surface of the first insulating film 106 including the upper surface of the first copper wire 107A. Similarly, a second insulating film 109A made of silicon oxide, for example, is formed on the first anti-diffusion film 108A, a second copper wire 107B is formed by a damascene method, for example, in the second insulating film 109A, and a second anti-diffusion film 108B made of silicon carbide or silicon nitride, for example, is provided on the upper surface of the second insulating film 109A including the upper surface of the second copper wire 107B. Similarly, a third insulating film 109B made of silicon oxide, for example, is formed on the second anti-diffusion film 108B, a third copper wire 107C is formed by a damascene method, for example, in the third insulating film 109B, and a third anti-diffusion film 108C made of silicon carbide or silicon nitride, for example, is provided on the upper surface of the third insulating film 109B including the upper surface of the third copper wire 107C. A fourth insulating film 109C made of silicon oxide, for example, is formed on the third anti-diffusion film 108C.

In the present embodiment, a barrier metal layer made of a layered structure of a tantalum film and a tantalum nitride film, for example, may be formed so as to cover the bottom surface and the side surface of each of the copper wires 107A-107C. Each of the copper wires 107A-107C may be a wire structure formed by a dual damascene process, for example, including as an integral unit a wire groove and a via hole extending from the bottom surface of the wire groove to reach to a wire of a lower layer, etc. The anti-diffusion films 108A-108C prevent the diffusion of copper of the copper wires 107A-107C, respectively.

As shown in FIG. 1, the insulating film layered structure including the insulating films 106 and 109A-109C, and the anti-diffusion films 108A-108C is also formed on a portion of the semiconductor substrate 100 in the pad electrode region RB outside the image sensing region RA. A pad electrode 116 made of aluminum, for example, is formed on a portion of the fourth insulating film 109C in the pad electrode region RB. A passivation film 110 is deposited on the fourth insulating film 109C including the pad electrode 116, and an opening 117 for wire bonding is formed by dry etching, etc., for example, in a portion of the passivation film 110 over the pad electrode 116.

On the other hand, as shown in FIG. 1, in the image sensing region RA, a depressed portion (waveguide depressed portion) 150 is formed in a portion over the photodiode 101 of the insulating film layered structure including the insulating films 106 and 109A-109C and the anti-diffusion films 108A-108C.

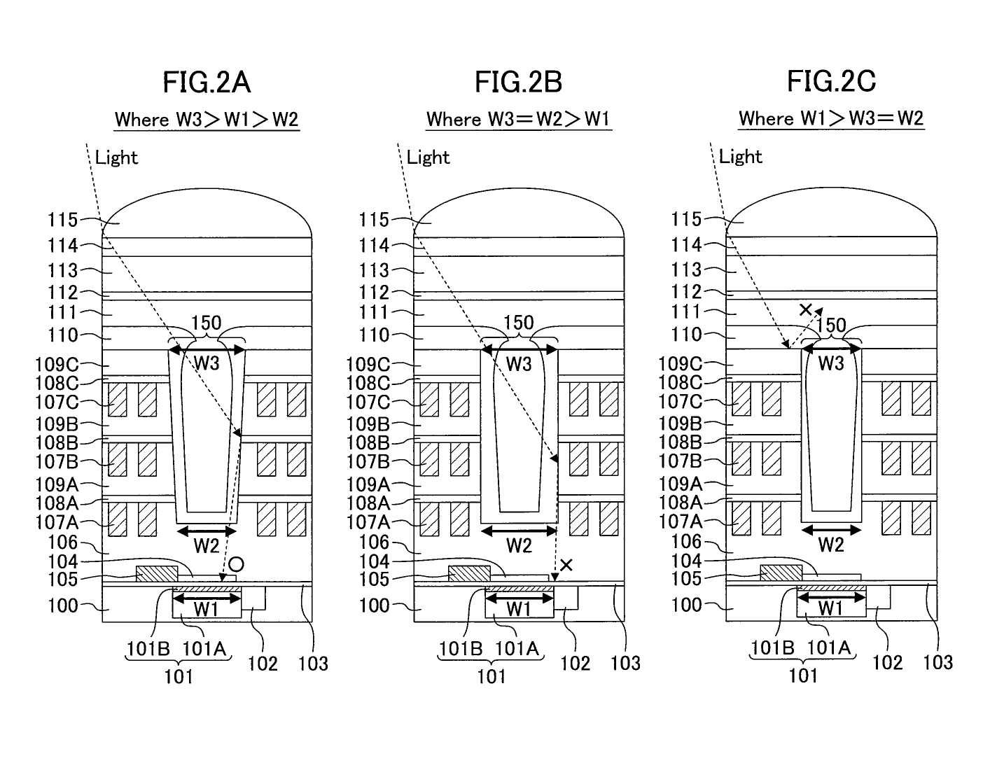

In the present embodiment, in order to efficiently condense light even when the photodiode area is reduced following advancements in the miniaturization of pixel cells, it is preferred that the area of the bottom surface of the depressed portion 150 is smaller than the area of the photodiode 101 (accurately, the area on a plane parallel to the light-receiving surface of the semiconductor substrate 100; this applies throughout the present specification), and the opening area of the uppermost portion of the depressed portion 150 is larger than the area of the photodiode 101. The reason will now be described with reference to FIGS. 2A-2C. First, as can be seen from a comparison between FIG. 2A and FIG. 2B, it is preferred that W1>W2 because if the width (corresponding to the area; this applies throughout the present specification) W2 of the bottom surface of the depressed portion 150 is larger than the width W1 of the photodiode 101 as is the width W3 of the uppermost portion of the depressed portion 150, light propagating along the side wall of the depressed portion 150 no longer enters the photodiode 101, thus decreasing the light condensing efficiency (sensitivity). Next, as can be seen from a comparison between FIG. 2A and FIG. 2C, it is preferred that W3>W1 because if the width W3 of the uppermost portion of the depressed portion 150 is smaller than the width W1 of the photodiode 101 as is the width W2 of the bottom surface of the depressed portion 150, the amount of light entering the depressed portion 150 is reduced. As described above, when W3>W1>W2, it is possible to efficiently condense light onto the photodiode 101 while maintaining a large amount of light entering the depressed portion 150. In this case, it is necessary to incline the side wall surface of the depressed portion 150 (i.e., to increase the cross sectional area of the depressed portion 150 at positions further away from the substrate surface), and the inclination angle (the angle with respect to the normal direction of the substrate principal surface) is preferably about 3° or more in order to reliably fill up the depressed portion with a high-refractive-index material as will be described below, and it is preferably about 6° or less in order to ensure the performance as a waveguide. It is preferred that the side wall surface of the depressed portion 150 has a smooth shape with no inflection point. The reason is as follows. That is, if there is a corner shape that can be an inflection point on the side wall surface of the depressed portion 150, the high-refractive-index resin such as a siloxane-based resin, etc., for example, buried in the depressed portion 150 is likely to crack starting from such a position. Such a crack leads to a reliability problem, e.g., a decrease in the sensitivity due to light scattering. Note that the width W1 of the photodiode 101 is determined dependent on the pixel size, the process rule, etc., and the width W2 of the bottom surface of the depressed portion 150 and the width W3 of the uppermost portion of the depressed portion 150 are also determined dependent on the width W1 of the photodiode 101, the pixel size, the process rule, etc. For example, where the width W1 of the photodiode 101 is about 820 nm, for example, the width W2 of the bottom surface of the depressed portion 150 and the width W3 of the uppermost portion of the depressed portion 150 may be set to, for example, about 720 nm and about 920 nm, respectively. While the depressed portion 150 is laid out in areas surrounded by a plurality of wiring layers, it is preferred that the area of the depressed portion 150 is maximized as long as it does not overlap with the wiring layers in order to increase the light incidence efficiency.

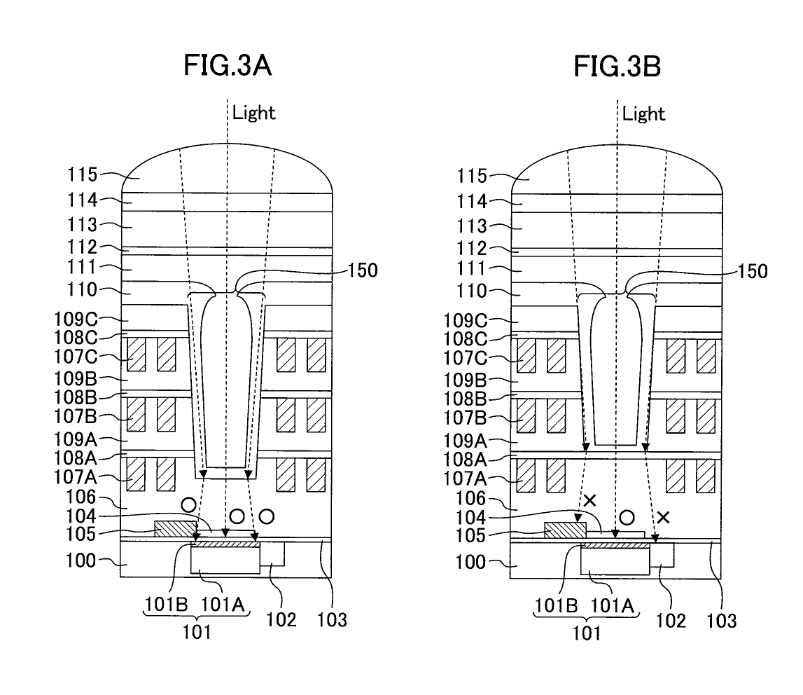

In the present embodiment, it is preferred that the bottom surface of the depressed portion 150 is closer to the substrate surface than the bottom surface of the lowermost anti-diffusion film (i.e., the first anti-diffusion film 108A). The reason will be described below with reference to FIGS. 3A-3B. The first reason is that, as shown in FIG. 3B, if the bottom surface of the depressed portion 150 is located above the bottom surface of the first anti-diffusion film 108A, the incident light is reflected by the first anti-diffusion film 108A, leading to a decrease in the sensitivity. The second reason is that, as shown in FIG. 3A, the incident light is more likely to be condensed onto the photodiode 101 as the bottom surface of the depressed portion 150 is closer to the substrate surface. That is, the depressed portion 150 guides the incident light to the vicinity of the substrate surface by the light confining effect of the high-refractive-index material, but in the area from the bottom surface of the depressed portion 150 to the substrate surface, the incident light moves away from the photodiode 101 due to light diffraction. Therefore, if there is a large distance from the bottom surface of the depressed portion 150 to the substrate surface as shown in FIG. 3B, the sensitivity decreases.

In the present embodiment, the aspect ratio of the depressed portion 150 may be set to about 1-2 or more, and the depth of the depressed portion 150 may be set to about 1500 nm, for example.

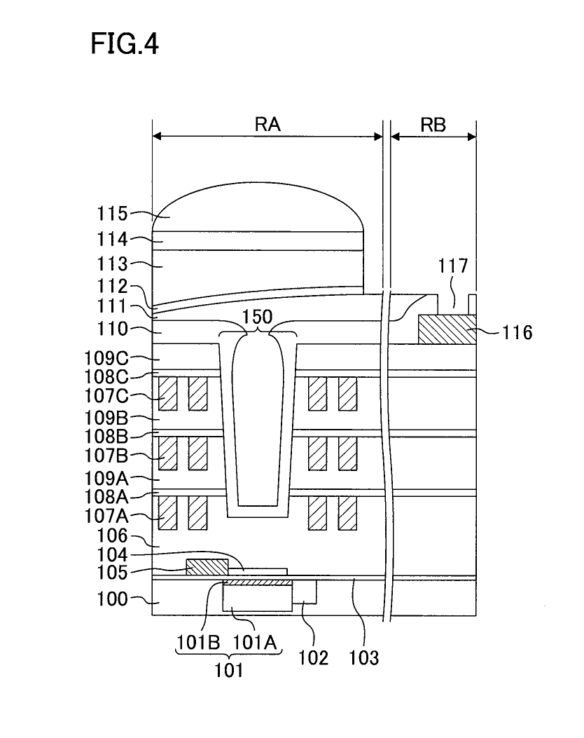

As shown in FIG. 1, the passivation film 110 having a higher refractive index than the refractive index 1.45 of silicon oxide of the insulating films 106 and 109A-109C is formed so as to cover the side surface and the wall surface of the depressed portion 150. Here, the passivation film 110 covers the surface of the fourth insulating film 109C in the image sensing region RA outside the depressed portion 150. As described above, the passivation film 110 is formed also on the fourth insulating film 109C in the pad electrode region RB so as to cover a portion of the pad electrode 116. The passivation film 110 may be a film having a thickness of about 0.4 μm made of silicon nitride (refractive index: 1.9-2.0), etc., for example. Note that due to anisotropy during deposition, the passivation film 110 is deposited thicker near the uppermost portion of the depressed portion 150 and is formed thinner near the bottom portion of the depressed portion 150. A buried layer 111 having a higher refractive index than silicon oxide is formed on the passivation film 110 so as to fill up the depressed portion 150. The buried layer 111 is formed so that the depressed portion 150 is completely filled up, and the thickness of the buried layer 111 outside the depressed portion 150 is about 0.6 μm which is generally equal to the thickness (about 600 nm) of the pad electrode 116, for example. Then, the distance from the substrate surface to the upper surface of the passivation film 110 on the pad electrode 116 can be made generally equal to the distance from the substrate surface to the upper surface of the buried layer 111. Note that if the distance from the substrate surface to the upper surface of the passivation film 110 on the pad electrode 116 is different from the distance from the substrate surface to the upper surface of the buried layer 111, as shown in FIG. 4, the thickness of the buried layer 111 in the image sensing region RA varies due to the nonuniformity in the thickness near the pad electrode 116. As a result, the thickness of a filter layer 113 to be described later to be formed on the buried layer 111 varies from pixel to pixel, and it is therefore likely that the light condensing efficiency (sensitivity) varies and the image quality lowers.

In the present embodiment, the buried layer 111 may be formed by a high-refractive-index resin such as, for example, a siloxane-based resin (refractive index: about 1.7-1.9) or a polyimide-based resin. The refractive index of the buried layer 111 can be increased to about 1.8-1.9 if such a high-refractive-index resin contains therein minute particles of a metal oxide such as titanium oxide, tantalum oxide, niobium oxide, tungsten oxide, zirconium oxide, zinc oxide, indium oxide, or hafnium oxide, for example.

In the present embodiment, the buried layer 111 is not formed on a portion of the passivation film 110 over the pad electrode 116. Alternatively, the buried layer 111 may be formed on the portion of the passivation film 110 over the pad electrode 116.

Moreover, as shown in FIG. 1, a flattening resin layer 112 that functions also as an adhesive layer, for example, is formed on the buried layer 111 in the image sensing region RA. Color filters of different colors of blue (B), green (G), and red (R), for example, (green is the color filter 113, while blue and red are not shown) are formed for each pixel on the flattening resin layer 112. A microlens 115 is formed on each color filter with a flattening layer 114 interposed therebetween. The flattening layer 114 reduces steps between different color filters of different colors.

Note that no color filter is formed in the pad electrode region RB. The various layers (the passivation film 110, the buried layer 111, the flattening resin layer 112, the flattening layer 114, and a resin layer forming the microlens 115) formed on the fourth insulating film 109C in the pad electrode region RB are opened so that upper surface of the pad electrode 116 is exposed therethrough.

In the solid-state imaging device of the present embodiment described above, an optical waveguide is formed by burying a high-refractive-index material in the depressed portion (waveguide depressed portion) 150 formed in a portion of the insulating film layered structure over the photodiode 101, and the passivation film 110 formed on the pad electrode 116 is buried in the depressed portion 150 as the high-refractive-index material. Therefore, an optical waveguide having a high heat resistance and a high refractive index can be formed through a simpler process.

With the solid-state imaging device of the present embodiment, the cross sectional area of the depressed portion 150 taken along a plane parallel to the light-receiving surface of the semiconductor substrate 100 gradually increases at positions further away from the light-receiving surface. Therefore, even if the depressed portion 150 has a large aspect ratio, by covering the side surface and the bottom surface of the depressed portion 150 with the relatively thin passivation film 110, e.g., a silicon nitride film, it is possible to prevent the passivation film 110 from blocking the entrance of the depressed portion 150 to form a void in the depressed portion 150. Therefore, the buried layer 111, e.g., a resin layer, can be formed on the passivation film 110 so as to completely fill up the depressed portion 150. That is, it is possible to fill up the depressed portion 150 with a high-refractive-index material without forming a void therein, and it is therefore possible to maintain a high light condensing efficiency as compared with a case where no waveguide is formed. Therefore, it is possible to maximize the condensation of light from the lens onto the photodiode, which is the basic function of a solid-state imaging device such as an image sensor, and it is therefore possible to realize a solid-state imaging device with a high sensitivity.

Note that in the present embodiment, the passivation film 110 formed on the pad electrode 116 is buried in the depressed portion 150 as the high-refractive-index material. Alternatively, a film made of a high-refractive-index material different from the passivation film 110 may be formed in the depressed portion 150 as a base layer under the buried layer 111.

In the solid-state imaging device of the present embodiment, it is possible to employ a configuration where logic circuits, etc., are mixed together on the same chip, for example. In such a case, the passivation film forming the optical waveguide (the passivation film 110 buried in the depressed portion 150) may be used as a passivation film also in another region such as a logic circuit region.

### Variation of First Embodiment

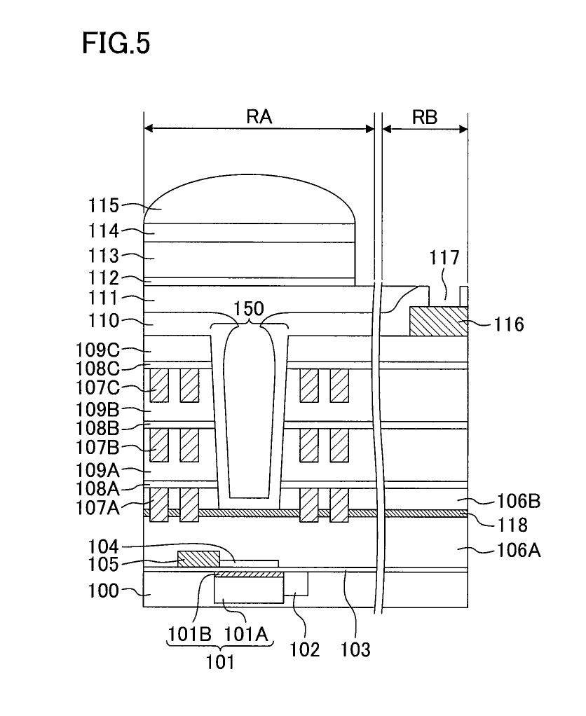

FIG. 5 is a cross-sectional view schematically showing a configuration of a solid-state imaging device according to a variation of the first embodiment. Note that FIG. 5 shows the configuration of one pixel from among a plurality of pixels provided in the image sensing region, together with the configuration of the pad electrode region. In FIG. 5, like elements to those of the first embodiment shown in FIG. 1 are denoted by like reference numerals, and will not be described redundantly.

This variation differs from the first embodiment in that, as shown in FIG. 5, an etch-stop layer 118 made of a silicon nitride layer, an SiOC layer, or the like, for example, is formed at a position that is closer to the substrate surface than the bottom surface of the lowermost anti-diffusion film (i.e., the first anti-diffusion film 108A), with the bottom surface of the depressed portion 150 coinciding with the upper surface of the etch-stop layer 118. That is, the distance from the substrate surface to the bottom surface of the depressed portion 150 is substantially equal to the distance from the substrate surface to the upper surface of the etch-stop layer 118. Here, an insulating film 106A under the etch-stop layer 118 and an insulating film 106B over the etch-stop layer 118 may each be formed by silicon oxide, for example.

According to this variation, when the depressed portion 150 is formed by using dry etching, the etching can be stopped at the etch-stop layer 118 by forming in advance the etch-stop layer 118. Therefore, pixel-to-pixel variations in the depth of the depressed portion 150 can be made very small, and it is therefore possible to reduce pixel-to-pixel variations in characteristics such as the light condensing efficiency (sensitivity). Therefore, it is possible to reduce variations in characteristics such as the sensitivity due to variations in the depth of the depressed portion 150 and to thereby improve the characteristics such as the sensitivity.

Note that in this variation, the etch-stop layer 118 is formed between the lower surface of the first anti-diffusion film 108A and the lower surface of the first copper wire 107A. Alternatively, the etch-stop layer 118 may be formed immediately under the first copper wire 107A or between the lower surface of the first copper wire 107A and the upper surface of the gate electrode 105.

What is claimed is:

1. A solid-state imaging device comprising:
a semiconductor substrate having, on a side of a light-receiving surface thereof, an image sensing region in which a plurality of pixels are formed;
a photodiode formed for each of the pixels of the semiconductor substrate;
a signal reading portion formed for each of the pixels of the semiconductor substrate for reading a signal charge produced by the photodiode;
an insulating film formed on the semiconductor substrate;
a depressed portion formed in a portion of the insulating film over the photodiode;
a first buried film covering a side surface and a bottom surface of the depressed portion and having a higher refractive index than the insulating film; and
a second buried film formed on the first buried film so as to fill up the depressed portion and having a higher refractive index than the insulating film,
wherein a cross sectional area of the depressed portion along a plane parallel to the light-receiving surface of the semiconductor substrate gradually increases at positions further away from the light-receiving surface of the semiconductor substrate.

2. The solid-state imaging device of claim 1, wherein
an area of the photodiode along a plane parallel to the light-receiving surface of the semiconductor substrate is larger than an area of the bottom surface of the depressed portion and smaller than an opening area of an uppermost portion of the depressed portion.

3. The solid-state imaging device of claim 1, wherein
the insulating film includes a plurality of insulating layers each having a wire buried therein and having an anti-diffusion layer on an upper surface side thereof, and
the bottom surface of the depressed portion is formed at a position that is closer to the light-receiving surface of the semiconductor substrate than the anti-diffusion layer closest to the light-receiving surface of the semiconductor substrate.

4. The solid-state imaging device of claim 3, further comprising
an etch-stop layer formed at a position that is closer to the light-receiving surface of the semiconductor substrate than the anti-diffusion layer closest to the light-receiving surface of the semiconductor substrate,
wherein a distance from the light-receiving surface of the semiconductor substrate to the bottom surface of the depressed portion is substantially equal to a distance from the light-receiving surface of the semiconductor substrate to an upper surface of the etch-stop layer.

5. The solid-state imaging device of claim 1, wherein
the insulating film is formed also in a pad region outside the image sensing region of the semiconductor substrate,
a pad electrode is formed on a portion of the insulating film in the pad region,
the first buried film is a passivation film formed on the insulating film so as to cover a portion of the pad electrode, and
a distance from the light-receiving surface of the semiconductor substrate to an upper surface of the second buried film is substantially equal to a distance from the light-receiving surface of the semiconductor substrate to an upper surface of a portion of the passivation film over the pad electrode.

6. The solid-state imaging device of claim 1, wherein
the first buried film is a silicon nitride film.

7. The solid-state imaging device of claim 1, wherein
the second buried film is a resin layer.

8. The solid-state imaging device of claim 7, wherein
the resin layer contains a siloxane-based resin.

9. The solid-state imaging device of claim 7, wherein
the resin layer contains a polyimide-based resin.
